(19) United States
(12) Patent Application Publication
(10) Pub. No.: US 2009/0206825 A1
(43) Pub. Date: Aug. 20, 2009

(54) EXCITATION AND MEASUREMENT METHOD FOR A MAGNETIC BIOSENSOR

(75) Inventor: Hans Marc Bert Boeve, Hechtel-Eksel (BE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/720,358

(22) PCT Filed: Nov. 22, 2005
(86) PCT No.: PCT/IB2005/053871

§ 371 Date: Mar. 31, 2009

Related U.S. Application Data
(60) Provisional application No. 60/522,989, filed on Nov. 30, 2004.

(51) Int. Cl. G01R 33/12; G06F 19/00

(52) U.S. Cl. 324/204; 702/19

(57) ABSTRACT

The present invention relates to an excitation and measurement method for a magnetic biosensor. Using at least a digital magnetic sensor element (100) a magnetic bead (110) is magnetized such that a magnetic stray field of the magnetic bead (110) prevents switching of a magnetic element (108) of the at least a digital magnetic sensor element (100) when the magnetic bead (110) is in close proximity to the top surface of the at least a digital magnetic sensor element (100). Measuring of the state of the magnetic element (108) allows the determination of a presence or non-presence of a magnetic bead (110). The method is highly advantageous by employing MRAM technology in biosensor systems.

This invention relates generally to magnetic sensors and in particular to an excitation and measurement method for a magnetic biosensor.

A magnetic biosensor system comprises an array of magnetic sensor elements coated with a biochemical layer capable of bonding with molecules of a predetermined species of molecules. Magnetic beads are activated with a biochemical coating that selectively bonds with molecules of the predetermined species. The biochemically activated beads are placed into a given solution where the biochemical coating of the beads bonds with molecules of the predetermined species, if present. After this process, molecules of the predetermined species are tagged by a magnetic bead. Once the solution is brought into contact with the biochemical layer of the magnetic sensor elements, tagged molecules of the predetermined species, diffuse to the biochemical layer and the molecules bond therewith. Presence or non-presence of the magnetic beads is measured at each magnetic sensor element based upon the magnetic properties of the beads.

The magnetic beads are either ferromagnetic—larger—or superparamagnetic—smaller—with the terms larger/smaller referring to the product magnetization volume of the bead. Magnetic beads that are superparamagnetic need to be magnetized first and after magnetization their stray field is measured using a magnetic sensor. An external magnetic field pulse is used for magnetizing superparamagnetic beads. Ideally, the external magnetic field pulse does not influence the sensor function.

Currently, magnetic biosensor systems are based on analog magnetic sensors for measuring Anisotropic or Giant MagnetoResistance (AMR or GMR). In parallel, non-volatile Magnetoresistive Random Access Memories (MRAM) have been developed based on bistable magnetic memory elements. Memory elements are employable as digital magnetic sensors when an extra magnetic field is used for influencing the switching of such a memory element.

Typically, MRAM devices rely on Tunnel MagnetoResistance (TMR) rather than AMR or GMR. However, bistable magnetic memory operation is not limited to TMR devices only, as is the digital magnetic sensor concept. Using a MRAM array enables use of a common platform with numerous different applications in biosensor systems, substantially reducing development and manufacturing cost.

However, in order to efficiently employ MRAM technology in biosensor systems there is a need for a simple, efficient and accurate excitation and measurement method employing MRAM technology.

It is, therefore, an object of the invention to provide an excitation and measurement method for a magnetic biosensor employing MRAM technology.

It is further an object of the invention to provide an excitation and measurement method for a magnetic biosensor employing MRAM technology that is simple, efficient and accurate.

In accordance with the present invention there is provided a method for sensing a presence of a magnetic bead comprising: providing at least a digital magnetic sensor element, the digital magnetic sensor element comprising a magnetic element, a bit line, and a word line, the word line oriented orthogonal to the bit line; measuring an initial state of the magnetic element of the at least a digital magnetic sensor element; providing a predetermined current pulse to each of the bit line and the word line of the at least a digital magnetic sensor element, the current pulses being capable of switching the state of the magnetic element of the at least a digital magnetic sensor element; measuring a first state of the magnetic element of the at least a digital magnetic sensor element after provision of the current pulses; and, comparing the measured first state of the magnetic element of the at least a digital magnetic sensor element with the initial state and providing a comparison result in dependence thereupon.

In accordance with the present invention there is further provided a storage medium having data stored therein, the data for when executed resulting in a method for sensing a presence of a magnetic bead using at least a digital magnetic sensor element comprising a magnetic element, a bit line, and a word line, the word line oriented orthogonal to the bit line, the method comprising: measuring an initial state of the magnetic element of the at least a digital magnetic sensor element; providing a predetermined current pulse to each of the bit line and the word line of the at least a digital magnetic sensor element, the current pulses being capable of switching the state of the magnetic element of the at least a digital magnetic sensor element; measuring a first state of the magnetic element of the at least a digital magnetic sensor element after provision of the current pulses; and, comparing the measured first state of the magnetic element of the at least a digital magnetic sensor element with the initial state and providing a comparison result in dependence thereupon.

In accordance with the present invention there is yet further provided a digital magnetic sensor system for sensing a presence of a magnetic bead comprising: at least a digital magnetic sensor element, the at least a digital magnetic sensor element comprising a magnetic element, a bit line, and a word line, the word line oriented orthogonal to the bit line, the at least a digital magnetic sensor element for sensing the presence of a magnetic bead in close proximity to its top surface; a processor in communication with the at least a digital magnetic sensor element, the processor for executing program data, the program data when executed resulting in a method for sensing the presence of a magnetic bead, the processor when executing the program data performing: measuring an initial state of the magnetic element of the at least a digital magnetic sensor element; controlling provision of a predetermined current pulse to each of the bit line and the word line of the at least a digital magnetic sensor element, respectively, the current pulses being capable of switching the state of the magnetic element of the at least a digital magnetic sensor element; measuring a first state of the magnetic element of the at least a digital magnetic sensor element after provision of the current pulses; and, comparing the measured first state of the magnetic element of the at least a digital magnetic sensor element with the initial state and providing a comparison result in dependence thereupon.

Exemplary embodiments of the invention will now be described in conjunction with the following drawings, in which:

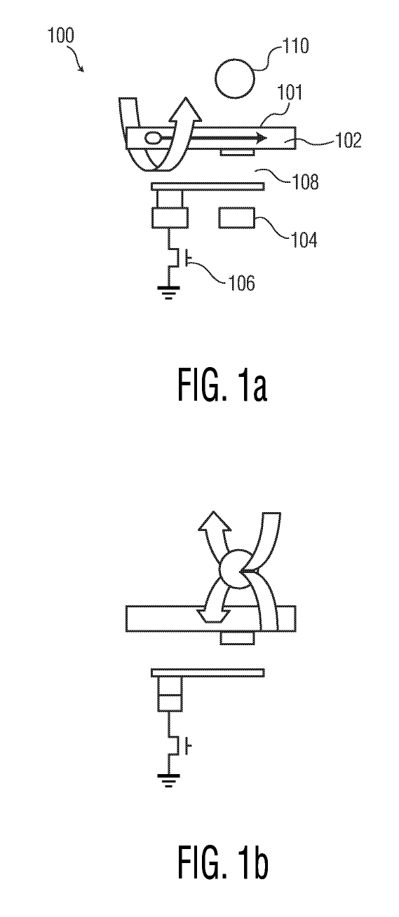

FIGS. 1a to 1d are simplified block diagrams schematically illustrating a digital magnetic sensor element in various modes of operation of an excitation and sensing method according to the invention;

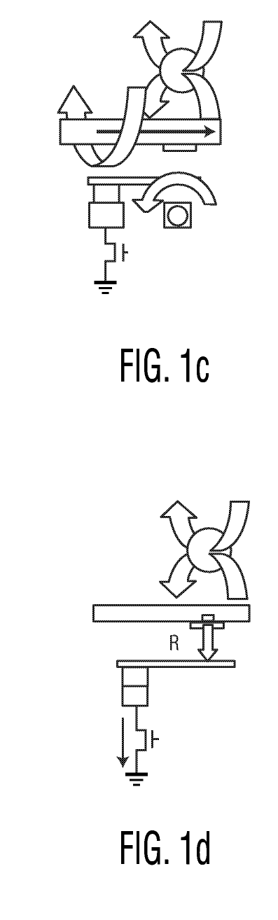

FIG. 2 is a simplified flow diagram of the excitation and sensing method according to the invention;

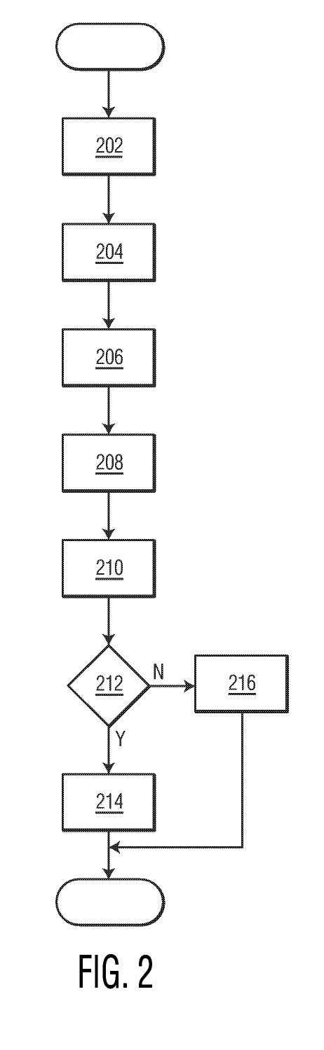

FIGS. 3a and 3b are simplified timing diagrams schematically illustrating operation of two embodiments of the excitation and sensing method according to the invention;

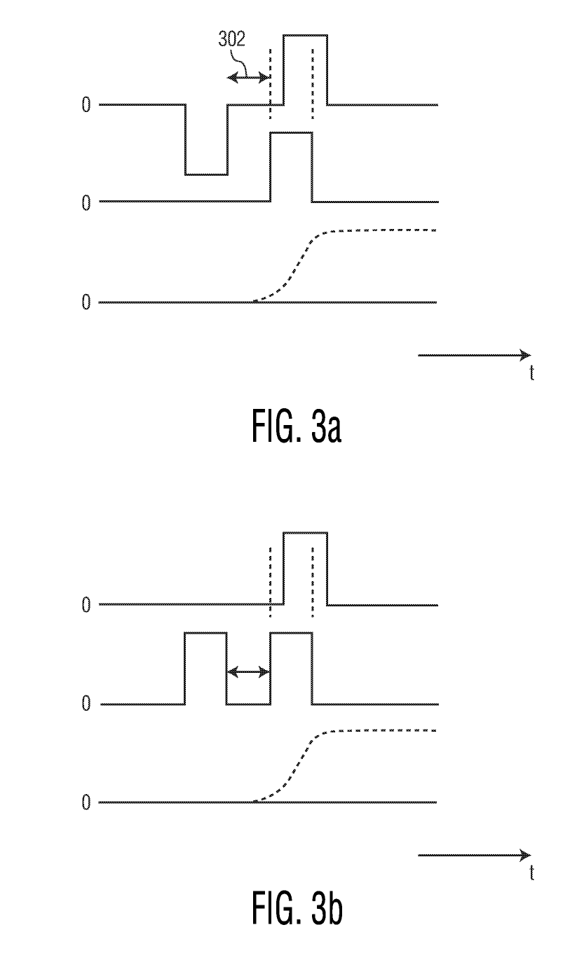

FIG. 4 is a simplified timing diagram schematically illustrating operation of another embodiment of the excitation and sensing method according to the invention;

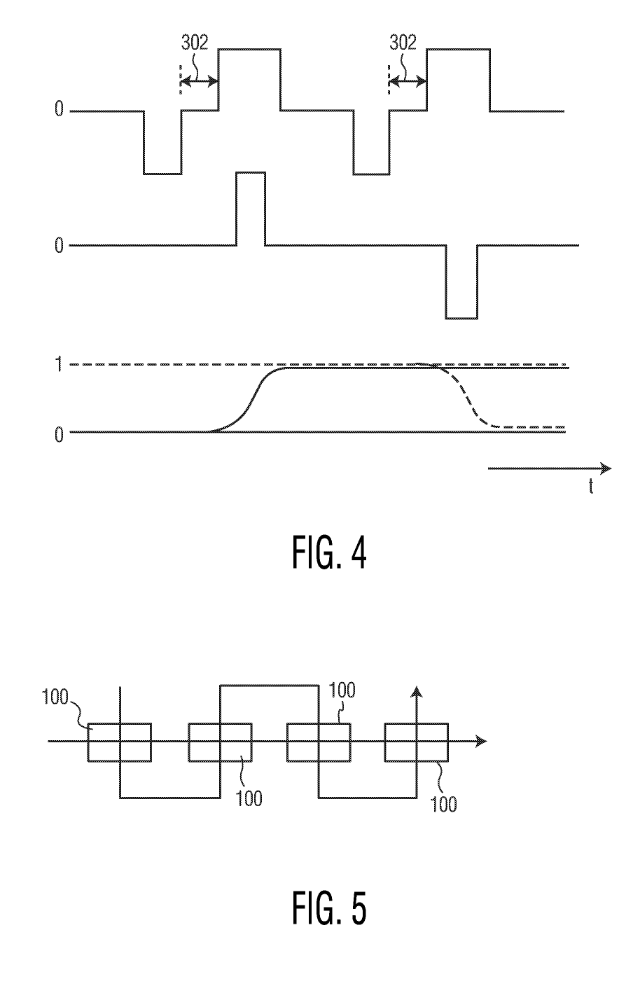

FIG. 5 is a simplified block diagram schematically illustrating a structure of an array of digital magnetic sensor elements for employing another embodiment of the excitation and sensing method according to the invention; and,

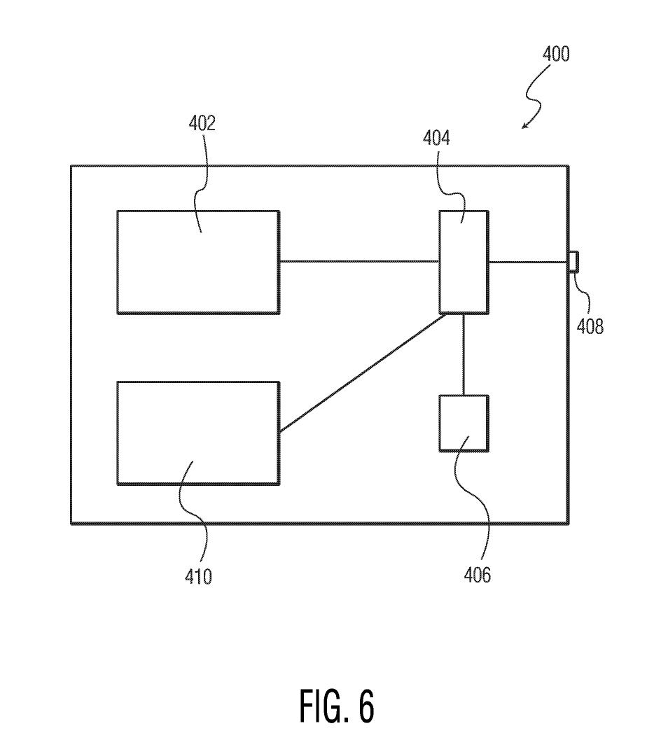

FIG. 6 is a simplified block diagram schematically illustrating a digital magnetic sensor system for employing the excitation and sensing method according to the invention.

Referring to FIGS. 1a to 1d, various modes of operation of a digital magnetic sensor element 100 of a MRAM for use as, for example, a biosensor element are shown. The digital magnetic sensor element 100 used for sensing the presence or non-presence of magnetic bead 110 has a typical layout of a MRAM memory element, based on Tunnel MagnetoResistance, known to one of skill in the art. The digital magnetic sensor element 100 basically comprises a bit line 102, a word line 104 oriented orthogonal to the bit line 102, a selection transistor 106, and a magnetic element 108. Typically, for application in biosensor systems magnetic beads 110 of nano-scale, referred to as “nano-beads,” are employed. Given the fact that the magnetic beads 110 are preferably superparamagnetic, the measurement process for sensing the presence or non-presence of the magnetic bead 110 according to the invention comprises principally two actions. In a first action the magnetic bead 110 when in close proximity to a top surface 101 of the digital magnetic sensor element 100 is magnetized and then, in a second action, a magnetic stray field of the magnetic bead 110 is sensed by the digital magnetic sensor element 100. A magnetic field pulse excites the superparamagnetic beads 110 to a predetermined magnetization, which decays with time. As a consequence, a time interval between the first and the second action is limited in order to ensure a sufficiently strong stray magnetic field of the magnetized bead 110 to be sensed by the digital magnetic sensor element 100. It is noted, that in case of ferromagnetic beads it is possible to omit the first action of excitation but is helpful in aligning the magnetic bead 110 with respect to the digital magnetic sensor element 100.

The magnetic beads 110 are magnetized in a magnetic field with a time constant given by a relaxation process. When the magnetic field is switched off, the magnetization of the magnetic beads 110 decays with a time constant according to the same relaxation. The equilibrium magnetic moment of a nano-bead in an applied magnetic field H and at a given temperature T is given by

$$m ( H , T ) = {m}_{0} L ( \frac{{m}_{0} {μ}_{0} H}{kT} ) \qquad ( 1 )$$

where L is the Langevin function, m0 he saturation magnetic moment for T=0 K, and μ₀ the magnetic constant, i.e. the product of saturation magnetization and magnetic volume. The Langevin function compares the magnetic energy delivered to the magnetic bead 110 with the thermal energy. The net magnetization is zero in absence of a magnetic field. After a magnetic field is applied at t=0, the magnetic moment per nano-bead increases according to

m(t,H,T)=m(H,T)(1−exp(−t/τ)) (2)

To magnetize nano-beads, a magnetic field pulse exceeding τ is needed to yield ≈70% of the equilibrium magnetic moment. After the magnetic field is switched off, the decay of the magnetization takes place within the same time frame. In the case that τ reflects Neel relaxation N, then

$${τ}_{N} = {τ}_{0} exp \frac{KV}{kT} \qquad ( 3 )$$

Moreover, it is possible to take Brownian motion into account with a relaxation time B

τ_{B}=3V_{η}/kT (4)

in which V denominates the magnetic volume of the nano-bead, and η the viscosity of a liquid disposed between the nano-bead 110 and the top surface 101 of the digital magnetic sensor element 100 (e.g. for water 10⁻³ Pa.s).

Given the fact that the time delay between the first and the second action is limited, it is likely not possible to measure the state of the magnetic element 108 between the two actions. Therefore, it is desired that the first action does not disturb the state of the magnetic element 108. In conventional MRAMs a single magnetic field component is normally not sufficient for switching the magnetic element 108, i.e. only a combination of two orthogonal magnetic field components is able to switch the magnetic element 108. In advanced MRAMs an even better selectivity is realized by ensuring that a single pulse is never able to switch the magnetic element 108, i.e. there is no restriction in the pulse height. A further description of conventional and advanced MRAM can be found in a variety of publications. For conventional MRAM one is referred to Tehrani et al, Proceedings of the IEEE, Vol. 91, No. 5, May 2003, Page 703-714. A publication introducing the advanced (or toggling) MRAM is by Durlam et al, IEDM Technical Digest 2003, Session 34, Paper #6.

Referring now to FIGS. 1a to 1b, 2, and 3a, a first embodiment of an excitation and measurement method for a magnetic biosensor using an advanced MRAM according to the invention will be described. In a first step—box 202—the state of the magnetic element 108 is measured. A single pulse is then sent into one of the bit line 108, shown in FIG. 1a, and the word line 104 to magnetize the bead 110—box 204. After a short delay, shown in FIG. 1b and in box 206, a double pulse is sent to the magnetic element 108, shown in FIG. 1c and box 208, by sending in short succession and with overlap one current pulse into the word line 104 and into the bit line 102, respectively. This action is followed by a second measurement of the state of the magnetic element 108, shown in FIG. 1d and box 210. As discussed above, the combination of two orthogonal magnetic fields causes the magnetic element 108 to switch. However, if this action is disturbed by the presence of a stray magnetic field of the magnetized bead 110 no switching action takes place. Therefore, if a change of state is detected—box 212—no magnetic bead is present—box 214—or if no change of state is detected—box 212—a magnetic bead is present—box 216. FIG. 3a illustrates schematically the timing of the current pulses in the bit line 102 and the word line 104 and the state of the magnetic element 108. In order to get an opposite sign in the magnetic field H_{bead} from the superparamagnetic bead 110 with respect to the magnetic field created from the bit line 102 in the double pulse, the polarity of the bit line pulse in the double pulse is inverted with respect to the first pulse for exciting the bead 110 as shown in FIG. 3a. As indicated in FIG. 3a, if there is no bead present, the state of the magnetic element is switched from 0 to 1. On the other hand, if there is a magnetized bead 110 present the magnetic element 108 remains in state 0. In an alternative embodiment the word line pulse is used to magnetize the magnetic bead, as shown in the timing diagram of FIG. 3b. Given the fact that in this particular embodiment the magnetic element 108 is placed between the word line 104 and the magnetic bead 110, a same current pulse direction is used for both actions, since the two magnetic fields are subtractive. Optionally, an external magnetic field pulse is used to magnetize the beads by using, for example, an external field coil.

The digital magnetic sensor element 100 senses a change-of-state in the magnetic element 108 upon electromagnetic excitation. In a preferred embodiment the excitation pulse is chosen to be identical to the switching pulses applied to a standard MRAM element. This is possible when the stray field caused by a magnetized bead 110 is large enough to prevent the magnetic element 108 from switching.

Tondra et al., J. Vac Sci. Technol. A 18.4, pp. 1125, 2000, published a calculation performed on a system comprising a single superparamagnetic bead and a GMR sensor. The measurement was performed using an externally applied field. The result of their calculation shows that the magnetic stray field H_{bead} created by the superparamagnetic bead is approximately 5-10% of the applied magnetic field Hₐₚₚ. Since H_{bead} has the opposite sign to Hₐₚₚ, the average total magnetic field during measurement is reduced to approximately 95%. Therefore, the sensor element measures a difference in switching threshold between the 100% field created during the single pulse of the first action and an approximately 95% field during the second action. In summary, Tondra et al. conclude that a GMR sensor is capable of detecting a single superparamagnetic bead of any size as long as the following conditions are met: (1) the sensor is approximately the same size as the bead, (2) the bead surface is approximately 0.2 bead radii away from the surface of the sensor, (3) the bead has a dimensionless magnetic susceptibility λₘ of 0.05, and (4) the GMR sensor response is adequate. Using a TMR based sensor all conditions are met, except condition (2). Since a contact must be provided on top of the TMR device, the distance between the bead surface and the sensor cannot follow the above scaling law. The digital magnetic sensor concept is generally applicable for AMR and GMR devices as well.

Referring to FIG. 4, a timing diagram of another embodiment of the excitation and measurement method according to the invention for use with conventional MRAMs is shown. Here the initial state of the magnetic element defines the direction of the current pulses in order to be able to induce a change of state. As shown in FIG. 4, two pulse trains, each comprising a single pulse for excitation of the bead and a double pulse for measurement, are provided, with the word line pulse of the second pulse train having opposite sign than the word line pulse of the first pulse train. As shown in FIG. 4, if the magnetic element is initially in state 0 the first pulse train causes the magnetic element to switch to state 1 when no bead is present, if the magnetic element is initially in state 1 the second pulse train causes the magnetic element to switch to state 0 when no bead is present. After each pulse train the state of the magnetic element is measured and compared with the measurement of the initial state of the magnetic element in order to determine the presence or non-presence of a magnetic bead.

Above, operation of a single digital magnetic sensor element has been described. It is to be noted that the implementation of a single digital magnetic sensor element 100 may comprise multiple magnetoresistive devices that are combined in a parallel and/or series connection into a single digital magnetic sensor. Alternatively, using MRAMs the digital magnetic sensor element 100 is one of a plurality of sensor elements arranged in a matrix-like array. Based on the array structure of the MRAM employed different techniques are applied to speed up the excitation and measurement process. For example, the single pulse event in a particular sensor element is performed simultaneously by sending a double pulse to one of the neighboring sensor elements, for example, by sharing one of the lines—bit line or word line—with the neighboring sensor element. However, according to an embodiment relying on this accelerated measurement technique either the state of the magnetic elements is measured between the first and the second action, or a set of measurements of the initial state of each digital magnetic sensor element is taken before sending pulses and is stored, for example, in a compatible memory such as a MRAM and the second measurement of the state of the magnetic elements is postponed until the complete array of digital magnetic sensor elements has been excited.

In an alternative embodiment a plurality of sensor elements 100 are disposed in parallel sharing a common bit line and word line, as shown in FIG. 5, enabling simultaneous excitation of the plurality of sensor elements 100. Furthermore, it is possible to arrange a plurality of such parallel sensor elements for forming a two-dimensional array of rows and columns. Again, a set of measurements of the initial state of each sensor element is taken before transmitting any pulses.

In a further embodiment repetitive measurements on a single sensor are taken to increase accuracy, either with a similar current pulse level—averaging, or with a varying current pulse level—discrete field sweep.

The excitation and measurement method according to the present invention is highly advantageous enabling use of MRAM memory technology for biosensor systems. A matrix of a plurality of sensor elements of a single MRAM chip is utilized for measuring magnetically tagged biological species. The method enables use of MRAM technology for producing a single bead event sensor allowing more detailed determination of concentration, or alternatively position mapping.

Referring now to FIG. 6, a biosensor system 400 for implementing an embodiment of the excitation and measurement method according to the invention is shown. The biosensor system 400 comprises a MRAM 402 used as an array of a plurality of biosensor elements. Processor 404 executes commands stored in memory 406 for controlling operation of the MRAM 402 for performing the process steps of one of the embodiments of the excitation and measurement method according to the invention. Depending on the array structure and the type—conventional or advanced—of the MRAM 402, one of the above embodiments is chosen for execution by the processor 404. Through port 408 the processor 404 receives control commands and provides measurement data. Optionally, the biosensor system comprises memory 410 in the form of MRAM for storing a set of measurements of the initial state of each sensor element. Preferably, the executable commands are hardware implemented for providing a simple and compact biosensor system on a single chip. Alternatively, the executable commands are stored on a portable medium in communication with the processor 404 or, further alternatively, are provided through port 408 connected to, for example, a workstation.

Numerous other embodiments of the invention will be apparent to persons skilled in the art without departing from the spirit and scope of the invention as defined in the appended claims.

What is claimed is:

1. A method for sensing a presence of a magnetic bead (110) comprising: providing at least a digital magnetic sensor element (100), the digital magnetic sensor element (100) comprising a magnetic element (108), a bit line (102), and a word line (104), the word line (104) oriented orthogonal to the bit line (102); measuring an initial state of the magnetic element (108) of the at least a digital magnetic sensor element (100); providing a predetermined current pulse to each of the bit line (102) and the word line (104) of the at least a digital magnetic sensor element (100), the current pulses being capable of switching the state of the magnetic element (108) of the at least a digital magnetic sensor element (100); measuring a first state of the magnetic element (108) of the at least a digital magnetic sensor element (100) after provision of the current pulses; and, comparing the measured first state of the magnetic element (108) of the at least a digital magnetic sensor element (100) with the initial state and providing a comparison result in dependence thereupon.

2. A method for sensing a presence of a magnetic bead (110) as defined in claim 1 comprising: providing a signal indicative of a presence of the magnetic bead (110) if the comparison result is indicative of a match; and, providing a signal indicative of a non-presence of the magnetic bead (110) if the comparison result is not indicative of a match.

3. A method for sensing a presence of a magnetic bead (110) as defined in any of claims 1 and 2 characterized in that providing the at least a digital magnetic sensor element (100) comprises providing at least a digital magnetic biosensor element for use in a biosensor system.

4. A method for sensing a presence of a magnetic bead (110) as defined in any of claims 1 to 3 comprising: providing a predetermined single current pulse to one of the bit line (102) and the word line (104) for magnetizing the magnetic bead (110) such that a magnetic stray field of the magnetic bead (110) prevents switching of the magnetic element (108) of the at least a digital magnetic sensor element (100) when the magnetic bead (110) is in close proximity to a top surface of the at least a digital magnetic sensor element (100).

5. A method for sensing a presence of a magnetic bead (110) as defined in any of claims 1 to 3 comprising: providing an external magnetic field pulse for magnetizing the magnetic bead (110) such that a magnetic stray field of the magnetic bead prevents switching of the magnetic element (108) of the at least a digital magnetic sensor element (100) when the magnetic bead (110) is in close proximity to a top surface of the at least a digital magnetic sensor element (100).

6. A method for sensing a presence of a magnetic bead (110) as defined in any of claims 1 to 5 characterized in that providing the at least a digital magnetic sensor element (100) comprises providing a plurality of magnetoresistive devices combined in one of series and parallel connection forming a digital magnetic sensor element.

7. A method for sensing a presence of a magnetic bead (110) as defined in any of claims 1 to 6 characterized in that providing the at least a digital magnetic sensor element (100) comprises providing an array of digital magnetic sensor elements.

8. A method for sensing a presence of a magnetic bead (110) as defined in claim 7 comprising storing data indicative of the initial state of each of the digital magnetic sensor elements (100) prior provision of the current pulses.

9. A method for sensing a presence of a magnetic bead (110) as defined in claim 1 comprising providing a second predetermined current pulse to each of the bit line (102) and the word line (104) of the at least a digital magnetic sensor element (100), the second current pulses being capable of switching the state of the magnetic element (108) of the at least a digital magnetic sensor element (100), wherein one of the second current pulses is inverted with respect to the corresponding first current pulse; measuring a second state of the magnetic element (108) of the at least a digital magnetic sensor element (100) after provision of the second current pulses; and, comparing the measured second state of the magnetic element (108) of the at least a digital magnetic sensor element (100) with the initial state and providing a second comparison result in dependence thereupon.

10. A method for sensing a presence of a magnetic bead (110) as defined in claim 9 comprising: providing a signal indicative of a presence of the magnetic bead (110) if the comparison result and the second comparison result are indicative of a match; and, providing a signal indicative of a non-presence of the magnetic bead (110) if one of the comparison result and the second comparison result is not indicative of a match.

11. A method for sensing a presence of a magnetic bead (110) as defined in any of claims 9 and 10 comprising: providing after measuring the initial state of the magnetic element (108) of the at least a digital magnetic sensor element (100) a predetermined single current pulse to one of the bit line (102) and the word line (104) of the at least a digital magnetic sensor element (100) for magnetizing the magnetic bead (110) such that a magnetic stray field of the magnetic bead (110) prevents switching of the magnetic element (108) of the at least a digital magnetic sensor element (100) when the magnetic bead (110) is in close proximity to a top surface of the at least a digital magnetic sensor element (100); and, providing after measuring the first state of the magnetic element (108) of the at least a digital magnetic sensor element (100) a second predetermined single current pulse to one of the bit line (102) and the word line (104) of the at least a digital magnetic sensor element (100) for magnetizing the magnetic bead (110) such that a magnetic stray field of the magnetic bead (110) prevents switching of the magnetic element (108) of the at least a digital magnetic sensor element (100) when the magnetic bead (110) is in close proximity to the top surface of the at least a digital magnetic sensor element (100).

12. A method for sensing a presence of a magnetic bead (110) as defined in any of claims 9 and 10 comprising: providing after measuring the initial state of the magnetic element (108) of the at least a digital magnetic sensor element (100) a predetermined external magnetic field pulse for magnetizing the magnetic bead (110) such that a magnetic stray field of the magnetic bead (110) prevents switching of the magnetic element (110) of the at least a digital magnetic sensor element (100) when the magnetic bead (110) is in close proximity to a top surface of the at least a digital magnetic sensor element (100); and, providing after measuring the first state of the magnetic element (108) of the at least a digital magnetic sensor element (100) a second predetermined external magnetic field pulse for magnetizing the magnetic bead (110) such that a magnetic stray field of the magnetic bead (110) prevents switching of the magnetic element (108) of the at least a digital magnetic sensor element (100) when the magnetic bead (110) is in close proximity to the top surface of the at least a digital magnetic sensor element (100).

13. A storage medium having data stored therein, the data for when executed resulting in a method for sensing a presence of a magnetic bead (110) using at least a digital magnetic sensor element (100) comprising a magnetic element (108), a bit line (102), and a word line (104), the word line (104) oriented orthogonal to the bit line(102), the method comprising: measuring an initial state of the magnetic element (108) of the at least a digital magnetic sensor element (100); providing a predetermined current pulse to each of the bit line (102) and the word line (104) of the at least a digital magnetic sensor element (100), the current pulses being capable of switching the state of the magnetic element (108) of the at least a digital magnetic sensor element (100); measuring a first state of the magnetic element (108) of the at least a digital magnetic sensor element (100) after provision of the current pulses; and, comparing the measured first state of the magnetic element (108) of the at least a digital magnetic sensor element (100) with the initial state and providing a comparison result in dependence thereupon.

14. A digital magnetic sensor system for sensing a presence of a magnetic bead (110) comprising: at least a digital magnetic sensor element (100), the at least a digital magnetic sensor element (100) comprising a magnetic element (108), a bit line (102), and a word line (104), the word line (104) oriented orthogonal to the bit line (102), the at least a digital magnetic sensor element (100) for sensing the presence of a magnetic bead (110) in close proximity to its top surface; a processor (404) in communication with the at least a digital magnetic sensor element (100), the processor (404) for executing program data, the program data when executed resulting in a method for sensing the presence of a magnetic bead (110), the processor (404) when executing the program data performing: measuring an initial state of the magnetic element (108) of the at least a digital magnetic sensor element (100); controlling provision of a predetermined current pulse to each of the bit line (102) and the word line (104) of the at least a digital magnetic sensor element (100), respectively, the current pulses being capable of switching the state of the magnetic element (108) of the at least a digital magnetic sensor element (100); measuring a first state of the magnetic element (108) of the at least a digital magnetic sensor element (100) after provision of the current pulses; and, comparing the measured first state of the magnetic element (108) of the at least a digital magnetic sensor element (100) with the initial state and providing a comparison result in dependence thereupon.

15. A digital magnetic sensor system for sensing a presence of a magnetic bead (110) as defined in claim 14 comprising a port (408) in communication with the processor (404) for providing at least a control signal to the processor (404) and for transmitting the comparison result.

16. A digital magnetic sensor system for sensing a presence of a magnetic bead (110) as defined in any of claims 14 and 15 characterized in that the digital magnetic sensor element (100) is designed for use as a digital magnetic biosensor element in a digital magnetic biosensor system

17. A digital magnetic sensor system for sensing a presence of a magnetic bead (110) as defined in any of claims 14 to 16 comprising first memory circuitry (406) in communication with the processor (404) for storing the program data.

18. A digital magnetic sensor system for sensing a presence of a magnetic bead (110) as defined in any of claims 14 to 17 characterized in that the at least a digital magnetic sensor element (100) comprises a plurality of magnetoresistive devices combined in one of series and parallel connection forming a digital magnetic sensor element.

19. A digital magnetic sensor system for sensing a presence of a magnetic bead (110) as defined in any of claims 14 to 18 characterized in that the at least a digital magnetic sensor element (100) comprises an array of digital magnetic sensor elements (402).

20. A digital magnetic sensor system for sensing a presence of a magnetic bead as defined in claim 19 characterized in that at least two of the digital magnetic sensor elements (100) share a common bit line (102) and a common word line (104) for simultaneous provision of a current pulse.

21. A digital magnetic sensor system for sensing a presence of a magnetic bead (110) as defined in any of claims 14 to 20 comprising second memory circuitry (410) in communication with the processor (404) for storing data indicative of the initial state of each of the digital magnetic sensor elements (100).

22. A digital magnetic sensor system for sensing a presence of a magnetic bead (110) as defined in any of claims 19 to 21 characterized in that the array of digital magnetic sensor elements (402) comprises an advanced MRAM.

23. A digital magnetic sensor system for sensing a presence of a magnetic bead (110) as defined in any of claims 19 to 21 characterized in that the array of digital magnetic sensor elements (402) comprises a conventional MRAM, and the processor (404) when executing the program data performing: providing a second predetermined current pulse to each of the bit line (102) and the word (104) line of the at least a digital magnetic sensor element (100), respectively, the second current pulses being capable of switching the state of the magnetic element (108) of the at least a digital magnetic sensor element (100), wherein one of the second current pulses is inverted with respect to the corresponding first current pulse; measuring a second state of the magnetic element (108) of the at least a digital magnetic sensor element (100) after provision of the second current pulses; and, comparing the measured second state of the magnetic element (108) of the at least a digital magnetic sensor element (100) with the initial state and providing a second comparison result in dependence thereupon.
